(19) United States
(12) Patent Application Publication
(10) Pub. No.: US 2024/0170912 A1
(43) Pub. Date: May 23, 2024

(54) COMPACT LASER SYSTEM FOR DIRECTED ENERGY APPLICATIONS

(71) Applicant: Optical Engines, Inc., Colorado Springs, CO (US)

(72) Inventors: Donald Lee Sipes, JR., Colorado Springs, CO (US); Eric John Pickron, Colorado Springs, CO (US); John R. Pickron, Colorado Springs, CO (US)

(21) Appl. No.: 18/514,172

(22) Filed: Nov. 20, 2023

Related U.S. Application Data
(60) Provisional application No. 63/427,316, filed on Nov. 22, 2022.

(51) Int. Cl. H01S 5/024; H01S 5/40

(52) U.S. Cl. CPC H01S 5/02423; H01S 5/02469; H01S 5/02476; H01S 5/4025

(57) ABSTRACT

A laser diode system is provided. The laser diode system comprises one or more laser diodes; a plurality of copper fins coupled to the laser diodes; and a cold plate comprising a plurality of copper fin cavities and an interior cavity. The plurality of copper fins are embedded within the plurality of copper fin cavities. A cooling medium is circulated through the interior cavity to cool the one or more laser diodes.

### CROSS REFERENCE TO RELATED APPLICATIONS

This application claims priority to U.S. Provisional Application No. 63/427,316, filed on Nov. 2, 2022, the entire contents of this application is being hereby incorporated by reference herein in its entirety.

### BACKGROUND

Laser diodes are useful in various different applications, including in military applications. However, while the high energy lasers required for certain direct energy (DE) applications output significant amounts of energy (e.g., 3 kilowatts (kW) of energy), they also require significant cooling operations for them to operate properly. For instance, traditionally, these laser diode systems may weigh a significant amount such as 55 kilograms (kg), but each of the laser diodes might only weigh 1 kg each. The majority of the weight of the laser diode systems are not from the laser diodes themselves, but rather their cooling systems. For instance, their cooling systems may weigh around 45 kg by themselves. Traditionally, to cool the laser diodes, water channels are installed within the laser diodes to flow water through the laser diodes to cool them (e.g., two input water channels and two output water channels). Thus, for a laser diode system with six laser diodes, this would include 24 water connections. Over time, these water connections could cause leakage issues and add to the overall weight of the system. As such, given the drawbacks including the potential water leakage as well as the extreme weight of the cooling systems, there remains a technical need to reduce the weight for laser diode systems while also ensuring the laser diodes are cooled properly.

### SUMMARY

This summary is provided to introduce certain exemplary embodiments that are further described below. This summary is not intended to be an identification of key features or essential features of the present disclosure.

In some examples, the present disclosure provides a laser diode system comprising: one or more laser diodes; a plurality of copper fins coupled to the laser diodes; and a cold plate comprising a plurality of copper fin cavities and an interior cavity, wherein the plurality of copper fins are embedded within the plurality of copper fin cavities, and wherein a cooling medium is circulated through the interior cavity to cool the one or more laser diodes.

In some instances, the present disclosure provides a cold plate comprising: a plurality of copper fin cavities, and an interior cavity, wherein a plurality of copper fins that are coupled to one or more laser diodes are embedded within the plurality of copper fin cavities, and wherein a cooling medium is circulated through the interior cavity to cool the one or more laser diodes.

In some variations, the present disclosure provides a method for cooling one or more laser diodes of a laser diode system, comprising: operating the one or more laser diodes to perform direct energy (DE) applications; and circulating, using a coolant pump, a cooling medium through a cold plate of the laser diode system to transfer waste heat from the one or more laser diodes to an outside environment, wherein a plurality of copper fins are coupled to the one or more laser diodes, wherein the plurality of copper fins are embedded within a plurality of copper fin cavities of an interior cavity of the cold plate, and wherein coolant pump circulates a cooling medium through the interior cavity to cool the one or more laser diodes.

Further features and aspects are described in additional detail below with reference to the figures.

### BRIEF DESCRIPTION OF THE DRAWINGS

FIGS. 1A-1C show a laser diode system with an enhanced cooling system according to one or more examples of the present disclosure;

FIGS. 2A-2D show a laser diode from the laser diode system according to one or more examples of the present disclosure;

FIGS. 3A-3E show the enhanced cooling system from the laser diode system according to one or more examples of the present disclosure;

FIG. 4 shows the operation of the enhanced cooling system within the laser diode system according to one or more examples of the present disclosure; and

FIGS. 5A-5F show another example of the laser diode system and implementations of using the laser diode system according to one or more examples of the present disclosure.

FIG. 6 shows a block diagram of the laser diode system according to one or more examples of the present disclosure.

### DETAILED DESCRIPTION

Among other applications, to address military requirements for advanced lightweight and reliable cooling systems to handle the high thermal transient environment facing today's modern laser weapons systems, the present disclosure provides a laser diode system with enhanced cooling systems. The present disclosure is based on a new configuration that utilizes a lightweight, high capacity, and highly reliable method for rejecting the many kilowatts (kW) of heat created in a direct energy (DE) fiber amplifier. The present disclosure is more effectively coupling the heat generated in the fiber laser pump to the overall cooling system, which significantly reduces the overall weight and pumping systems currently required by the DE lasers. This may enable the laser diode system of the present disclosure to reduce the amount of weight by an order of magnitude, which increases reliability and reduces water connections required by current low small size weight and power (SWAP) pump fiber coupled lasers. As a result, aspects of the present disclosure enable efficient two-phase cooling with greatly reduced system pressure requirements enabling low flow low pressure systems with vapor chamber like efficiencies enabling the use of high temperature diodes with greatly reduced cooling requirements. Modular open systems approach (MOSA) type DE fiber laser blades utilizing the present disclosure enables DE systems to be able to be placed in an increased number of platforms utilizing phase change materials for thermal transient moderation and also for high air flow airborne cooling systems, which directly addresses the requirements for a wide range of airborne and spaceborne platforms.

In some instances, the present disclosure may be used as DE laser weapons. For instance, with their time-of-flight engagement, and deep, low cost magazines, Directed Energy laser weapons have shown themselves to be a weapon with truly revolutionary potential to protect military assets as well as the populations they defend. By enabling large reduction in overall system weight, power and cost, aspects of the present disclosure enable the wide deployment of these laser weapons on a wide array of platforms to allow DE technology to have its maximum beneficial impact.

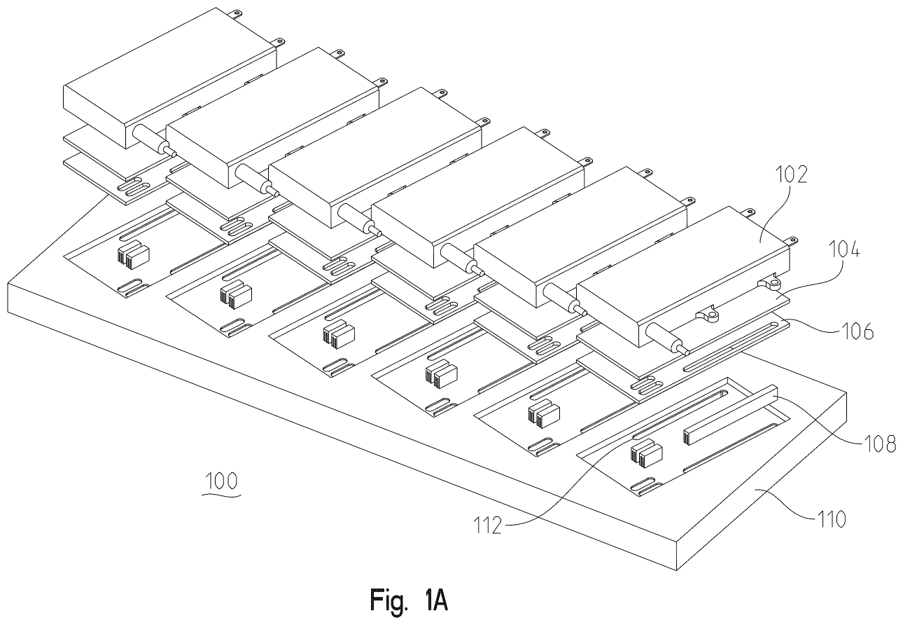

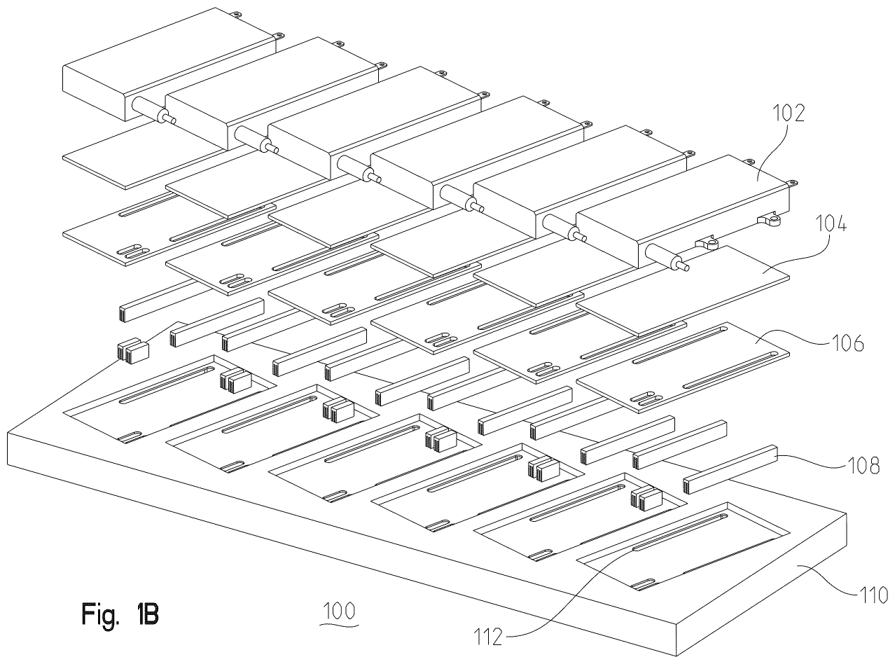

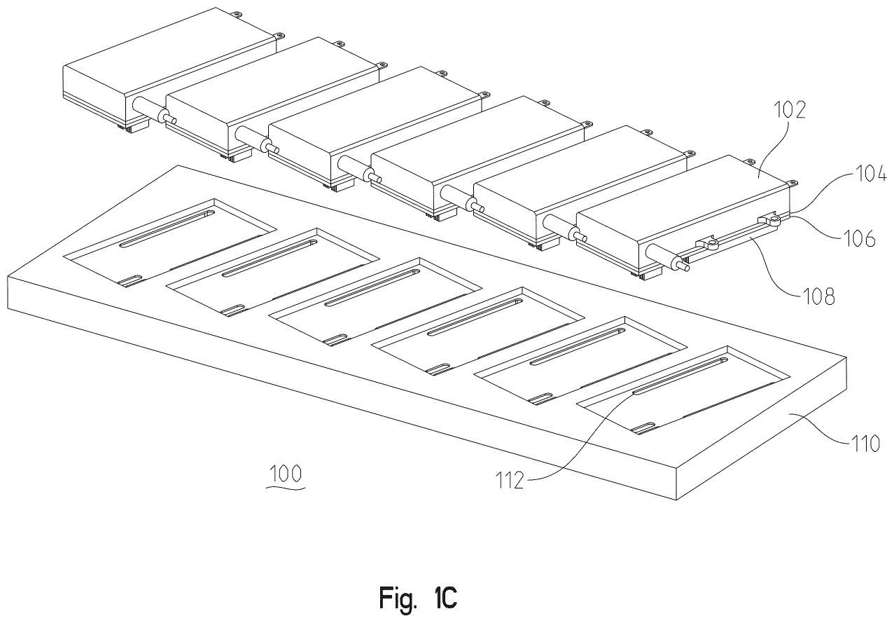

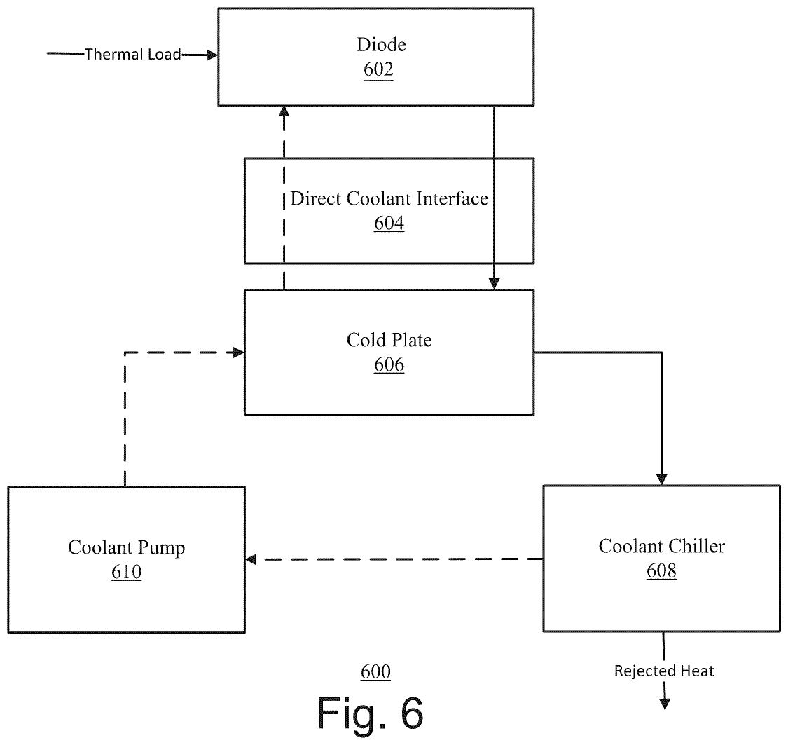

Aspects of the present disclosure will be described in further detail below. FIGS. 1A-1C show a laser diode system 100 with an enhanced cooling system (e.g., the enhanced cooling system 600 shown in FIG. 6 and described below). For instance, referring to FIG. 1A, an exploded view of the laser diode system 100 is shown. The system 100 includes diodes 102 (e.g., E-24 diodes), copper heat spreaders 104, aluminum seals 106, copper fins 108, and a cold plate 110. The components of system 100 are merely exemplary and may include additional and/or alternative components. For instance, the diodes 102 can be any type of diode that is configured to provide enough power for the DE applications. In operation, in contrast to traditional systems, the cold plate 110 is configured to produce an enhanced cooling system that enables the diodes 102 to maintain operation while still being able to perform the required DE application. For example, certain components of the diodes 102 generate enormous amount of heat in operation, but the diodes 102 cannot tolerate a significant rise in temperature. For instance, for certain diodes, the diodes may fail if they reach more than 10 degrees Celsius over the ambient temperature. Accordingly, massive cooling operations need to be performed to ensure the diodes 102 operate within a certain temperature range. Unfortunately, as mentioned above, traditional systems use cooling systems that add a significant amount of weight to the overall system and thus are undesired for SWAP lasers. Accordingly, the present disclosure uses an enhanced cooling system (e.g., a cold plate 110) for cooling the laser diodes 102. For instance, the copper fins 108 are coupled to the components of the diodes 102 that generate the enormous amount of heat in operation. The cold plate 110 includes cavities 112 for the copper fins 108 such that the copper fins 108 are immersed into the cold plate 110. As such, in operation, the cold plate 110 is configured to cool the copper fins 108 and thus cool the diodes 102 without having any water channels inserted within the diodes 102 themselves. For instance, water, air, coolant and/or other types of cooling mediums (e.g., a liquid-based cooling medium such as coolant and/or water or an air-based cooling medium) may be circulated through the cold plate 110. In some instances, the cooling medium may be a two-phase cooling medium such as water, other two-phase refrigerants, and/or a gas-based cooling medium (e.g., air or FREON R-134a refrigerant circulating through the interior cavity). Based on the circulation and the copper fins 108 being coupled to the cold plate 110, the copper fins 108 are cooled by the cold plate 110. As such, because the copper fins 108 are coupled to the components of the diodes 102 that generate the majority of the heat during operation of the diode 102, this in turn cools the diode 102. For instance, the laser diodes may be separated into a first portion and a second portion. Comparatively, the first portion of the laser diodes may generate significantly more heat than the second portion of the laser diodes. As such, the copper fins 108 are coupled to (e.g., attached to and/or placed on) the first portion of the laser diodes. By using the cold plate 110, this has the advantage of not introducing any leakage issues with the input/output water channels that could damage the diodes 102. The laser diode system 100 with the enhanced cooling system will be described in further detail below. In some examples, the copper heat spreader 104 is in contact with portions of diode 102 that generate much of the waste heat generating during operation of the laser diode system 100. Copper heat spreader 104 serves to prevent waste heat from staying trapped at or near the diode 102, which may cause temperatures to rise to unsafe levels, potentially damaging the diode 102. The aluminum seal 106 provides a seal against leakage of the cooling medium. In some examples, the seal 106 is an aluminum seal. In other embodiments, such seals 106 may include Teflon seals, crush spiral wound gasket seals, composite aluminum-and-O ring or gasket seals, and/or more sophisticated sealing mechanisms such as mechanical seals.

FIGS. 1B and 1C also show the laser diode system 100 of FIG. 1A. For instance, FIG. 1B shows another exploded view of the laser diode system 100. FIG. 1C shows the diodes 102, copper heat spreaders 104, aluminum seals 106, and copper fins 108 being assembled and separate from the cold plate 110. The copper fins 108 that are at the bottom of the top diode assembly are inserted into cavities 112 of the cold plate 110 so as to cool the diode 102 during operation. Copper heat spreaders 104 and aluminum seals 106 are positioned between diodes 102 and cold plate 110.

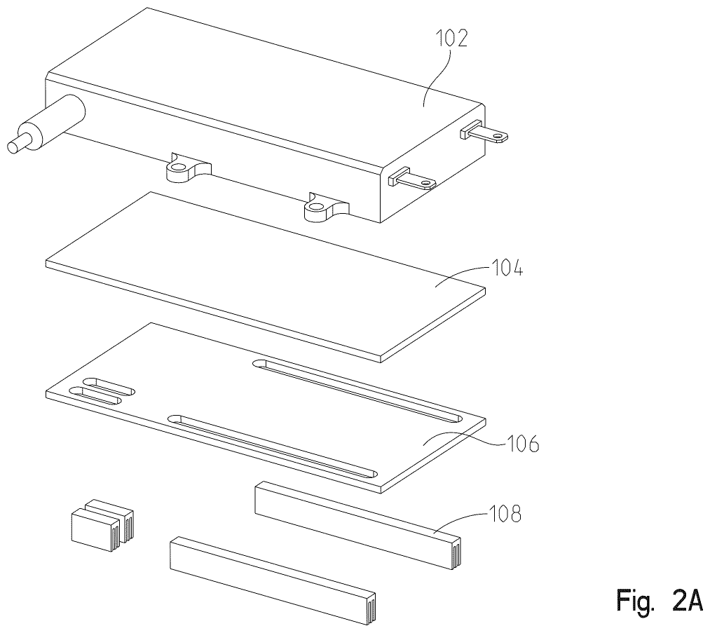

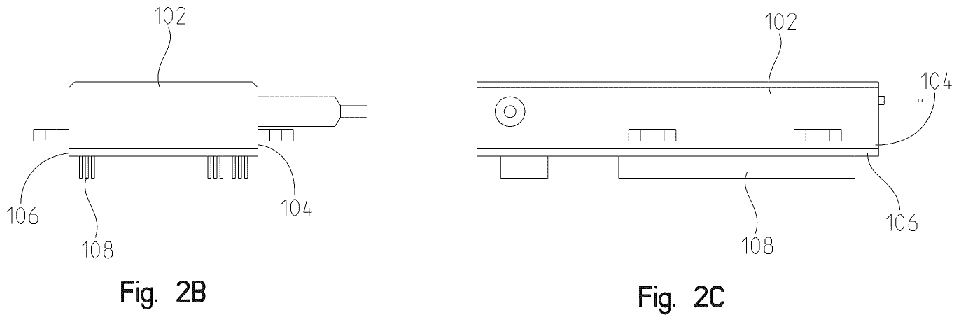

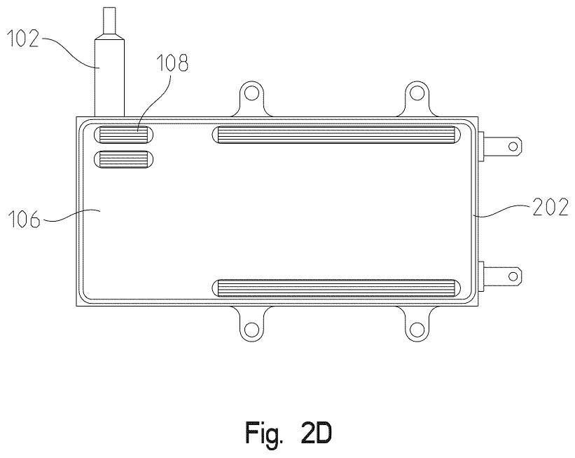

FIGS. 2A-2D show a single laser diode 102 and its associated components from the laser diode system. For example, FIG. 2A shows an exploded view of the laser diode 102 along with the copper heat spreaders 104, aluminum seals 106, and copper fins 108. FIG. 2B shows a side view of the laser diode 102 with its associated components, including the diode 102, copper heat spreader 104, aluminum seal 106, and copper fins 108. FIG. 2C shows another side view of the laser diode 102 with its associated components, including the diode 102, copper heat spreader 104, aluminum seal 106, and copper fins 108. Referring to FIG. 2C, the copper fins 108 are encased within a structure that may be of similar dimensions to the cavity of the cold plate (e.g., cavity 112) and may be inserted into the cavity from the cold plate 110. FIG. 2D shows a bottom view of the laser diode 102 with its associated components. For instance, the aluminum seal 106, the O-ring channel 202, and the copper fins 108 are shown. In particular, as mentioned above, certain components of the laser diode 102 generate the majority of heat during operation of the laser diode 102. For instance, the first portion of the laser diode 102 may include the portions coupled to the copper fins 108 (e.g., the portions that are vertically-aligned to the copper fins 108) and the second portion of the laser diode 102 may be the other portions of the laser diode 102. The copper fins 108 are coupled to the components that generate the majority of the heat. As such, by cooling the copper fins 108, the overall diode 102 may be cooled so that it can operate in the necessary temperature ranges.

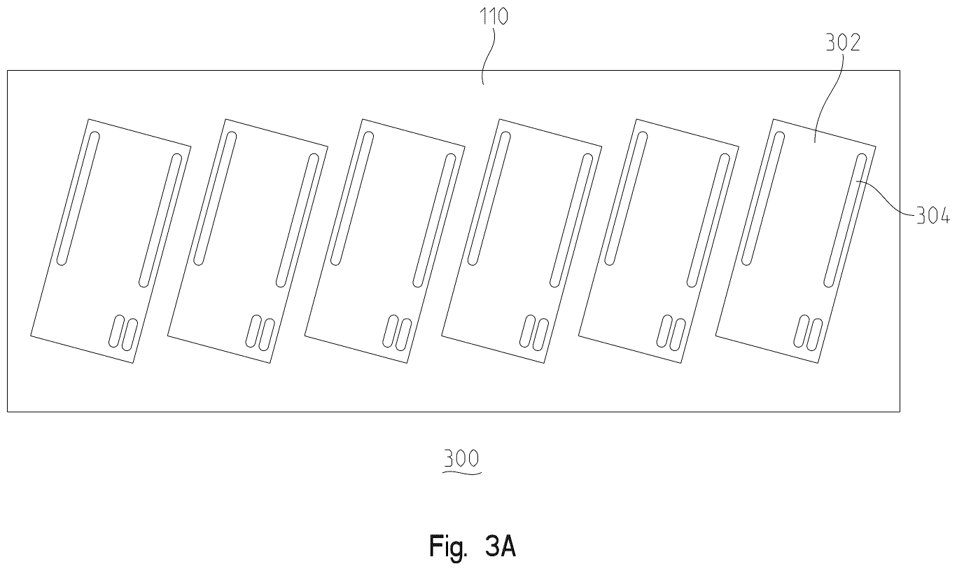

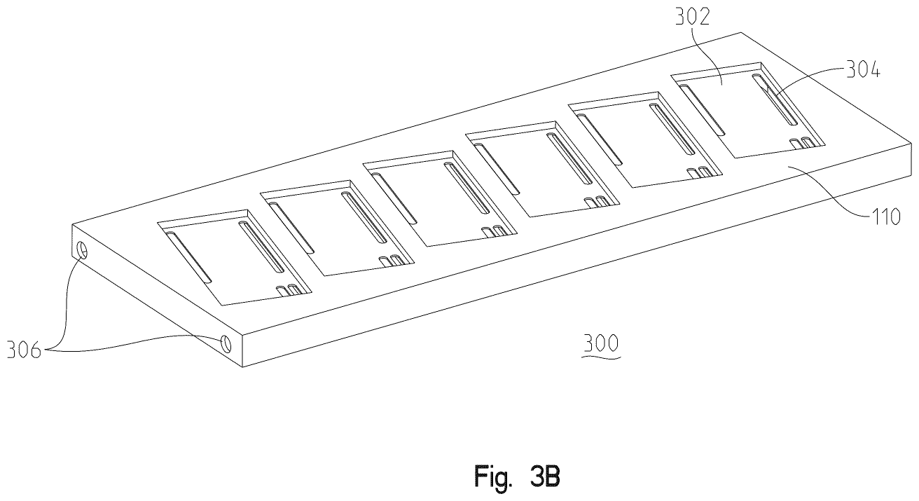

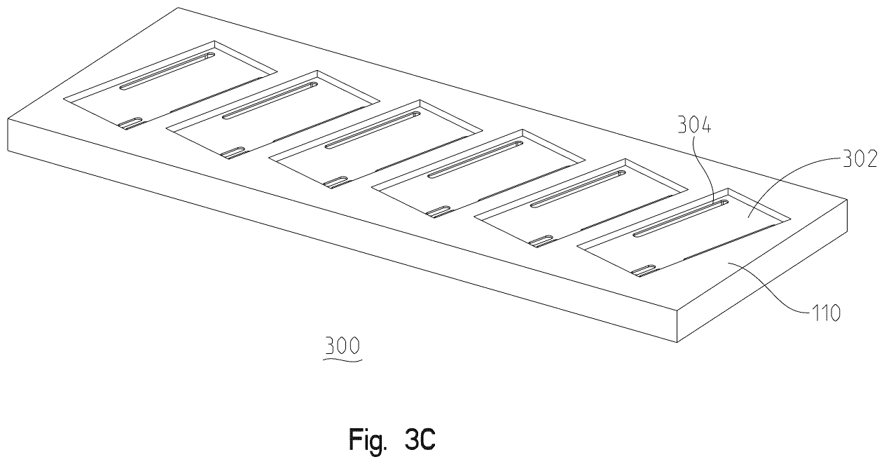

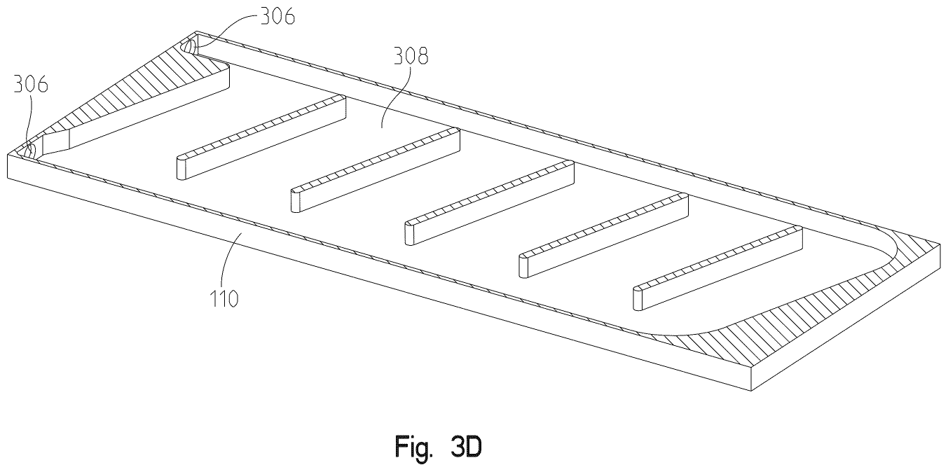

FIGS. 3A-3E show the enhanced cooling system 300 from the laser diode system. For instance, FIGS. 3A-3E show the cold plate 110 from FIG. 1. FIG. 3A shows a top view of the cold plate 110, and the assembly pockets 302 that are coupled to the laser diodes (e.g., the six assembly pockets 302 for the six laser diodes of the laser diode system such as the laser diodes 102 of FIG. 1A). Furthermore, the cold plate 110 includes copper fin passthroughs 304 (e.g., cavities 112) for the copper fins to be inserted into such that the cold plate 110 can cool the copper fins/laser diode. As shown, the copper fin passthroughs 304 are aligned to the copper fins as well as to the components of the laser diode that generate the majority of the heat when the laser diode is in operation. FIGS. 3B and 3C show the cold plate 110 from other angles. FIG. 3D shows the interior for the cold plate 110. For instance, as shown in FIGS. 3B and 3D, there are two openings 306 for the cooling medium to circulate through the cold plate 110. By using these openings 306, the copper fins and the laser diode can be cooled. The cooling medium may include water, air, coolant, and/or other types of cooling mediums. FIG. 3E shows a top view of the interior of the cold plate 110. Furthermore, FIG. 3E shows the interior cavity 308. The cooling medium may take a coolant path (e.g., the cooling medium path) to cool the copper fins and laser diode. In other words, the cold plate 110 comprises a plurality of copper fin cavities or cavities 112 and an interior cavity 308 for the coolant path. The cooling medium flows through the interior cavity 308, which is enclosed by the exterior of the cold plate 110, and thus the cooling medium is prevented from being in contact with the diodes 102.

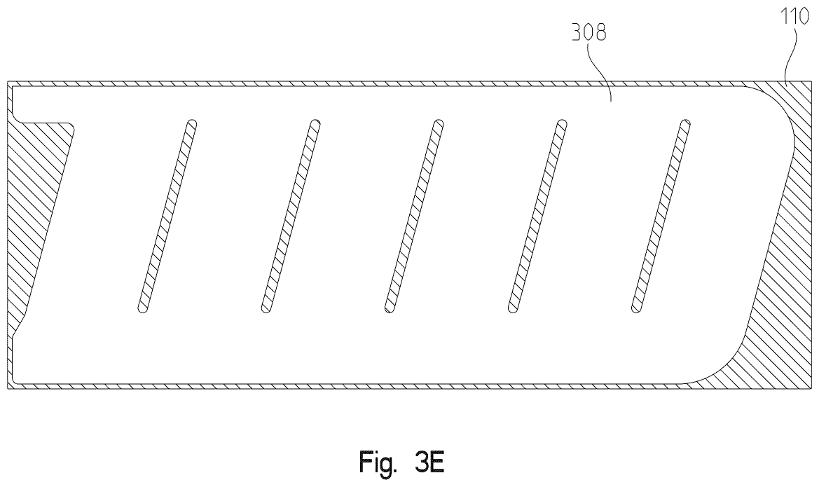

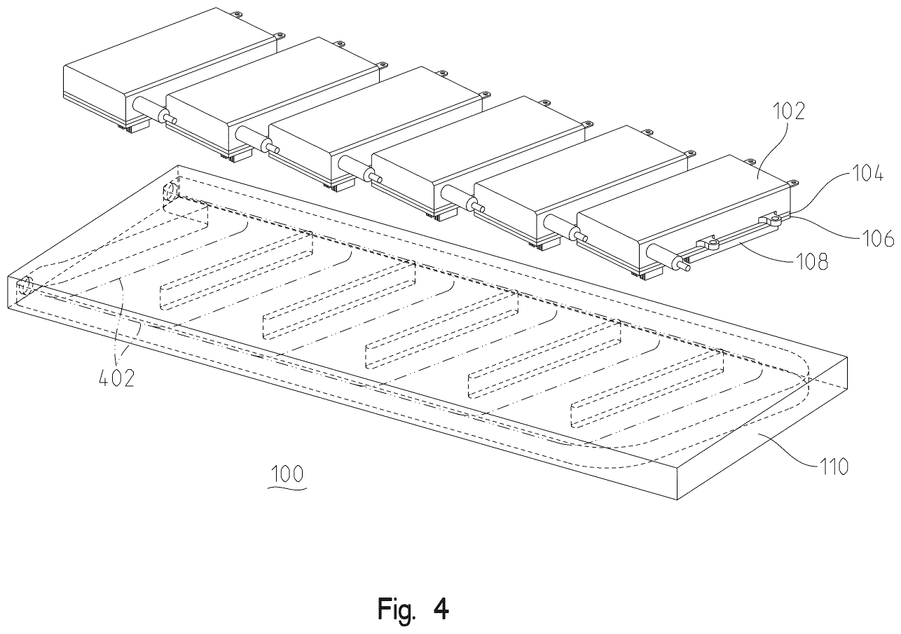

FIG. 4 shows the operation of the enhanced cooling system within the laser diode system 100. For example, FIG. 4 shows the circulation of the cooling medium within the interior of the cold plate(s) 110. For instance, dotted lines 402 show the potential flow paths for the cooling medium as the cooling medium is circulated within the interior of the cold plate 110.

As such, using the potential flow paths 402, aspects of the present disclosure may use the interior of the cold plate 110 to cool the laser diode 102 and the copper fins 108. For instance, referring to FIGS. 1B and 4, the cold plate 110 may include cavities 112 (e.g., copper fin passthroughs) for the copper fins 108 as well as flow cavities (e.g., the flow cavity 308 shown in FIG. 3E). In some instances, the flow cavities may be a 3-dimensional (3-D) printed hollow flow cavity. In other instances, the flow cavities may be an interior cavity with flow directors and baffles. When present, the flow directors or baffles within the interior cavity 308 of the cold plate 110 may cause turbulent flow of the cooling medium within the cold plate 110. In some variations, the cooled underside may further include mounting gain fiber and fiber amplifier components. By using the cold plate 110, the cooling medium (e.g., a coolant) may be as close to the laser diodes 102 as possible to cool the laser diodes 102. An O-ring may be used for sealing such that the components of the laser diode system 100 may be mounted together without warping the overall laser diode system. The copper fins 108 may be coupled to (bonded with) the bottom of the laser diode 102 (e.g., bonded to the copper heat spreader 104) through aluminum seal 106. The copper heat spreader 104 may be 1.5 inches thick. In some instances, the components of the laser diode 102 that are coupled to (e.g., next to) the copper fins 108 (e.g., the first portions of the laser diode) may generate around 90% of the overall heat (e.g., 90% of 500 Watts). The copper fins 108 may be any height that is necessary to obtain the best coupling with the flow (e.g., cooling medium) in order to cool the laser diode 102. In some examples, the interior of the cold plate 110 may be configured to have a cooling medium path that causes some turbulence within the interior of the cold plate 110, which would cause better heat dissipation. In some variations, baffles may be used in the cold plate 110 to ensure the cooling medium flow path is sufficient. The cooling medium may be any type of cooling medium that is used to cool the laser diode 102/copper fins 108 such as water, air, and/or a refrigerant (e.g., a two-phase refrigerant with 2-phase boiling point). In some embodiments, the cooling medium is a two-phase refrigerant, and the two phase refrigerant has a boiling point. The copper fins 108 have a plurality of surfaces in fluid communication with the cooling medium within the interior cavity 308 of the cold plate 110. During operation of the laser diode system 400, the plurality of surfaces of the copper fins 108 may reach temperatures above the boiling point of the two-phase refrigerant. This may initiate boiling at the plurality of surfaces of the copper fins 108 during operation of the laser diode system 100. In some embodiments, such surfaces of copper fins 108 may comprise a porous material, or be coated in such a material, to boil the two-phase refrigerant by contact with the plurality of surfaces of the copper fins 108, at a faster rate than a non-porous copper fin.

As mentioned above, the present disclosure (e.g., the laser diode systems 100 and/or 400) can be used for a variety of applications including military applications. For instance, in certain circumstances, a large salvo of hundreds of hypersonic missiles may be heading towards a military resource. Directed Energy (DE) laser technology with high power, low SWAP and low cost may provide the opportunity of an extensive deployment on wide range of platforms to prevent the missiles from hitting the military resource.

To make this a reality, significant innovative improvements in the engineering of DE laser weapons are required. To this end, significant investment in the development of Low SWAP, high brightness fiber coupled pumps have been performed. These investments have resulted in pump lasers (e.g., laser diodes 102) with significantly reduced weight over conduction cooled pump lasers. Unfortunately, these pump lasers have a glaring flaw: the pump laser manufacturers have reduced weight by running the fluid lines through the pump laser and adding input and output water connectors. A 3 kW DE fiber amplifier with six 600 W fiber coupled pumps with have 24 water connections with small water channels leading to numerous potential leaks and high pressure drops.

There have been traditionally different ways to cool pump laser diodes. The approach most used is conduction cooling. But these result in making the resulting laser amplifier unacceptably heavy.

Accordingly, to meet enhanced lightweight laser weapon cooling systems standards, the present disclosure presents a new High Performance Thermal Systems for Future Laser Weapons (e.g., laser diode systems 100 and/or 400) (LASERFLOW) that creates a DE fiber amplifier that is ultra-light weight, with low flow and pressure requirements and has no internal water connections.

The present disclosure may use a true “in the flow” laser diode (e.g., laser diode 102) cooling technology and closely couples the heat generating laser emitters (e.g., laser diodes 102) to the cooling fluid (e.g., cooling medium) without requiring mounting stress on the pump laser optics bench allowing for the optics bench to be much thinner and lighter weight.

The present disclosure includes a fiber coupled pump laser diode (e.g., laser diode 102). The very thick, heavy copper optics bench that holds the individual laser diodes 102 and the fiber coupling optics is made thinner with a stiffer material for structure and not heat flow. Pockets are created close to the strips of the laser emitters (e.g., laser diode 102) and fins (e.g., copper fins 108) are bonded to the bottom of the optics bench. These fins are coated with a porous material that is designed to facilitate boiling in a two-phase cooling liquid. The pump laser diode (e.g., laser diode 102) is mounted on a fluid or vapor flow cavity (e.g., the interior cavity 308) on a 1 or 2 O-ring structure to seal the pump unit to the flow cavity to prevent leaking of the cooling liquid (e.g., cooling medium). The cavity is large and turbulent flow is promoted using baffles. Multiple pump laser diodes may be mounted on a single flow cavity. This may allow for a very low pressure drop and a large volume of liquid which may provide for a reduced flow requirement. This flow cavity can also be a large vapor changer for environments where the heat may be conducted over a short distance to a heat exchanger, be it air or liquid based.

The present disclosure may use extensive thermal modeling and design to assemble and test/demonstrate feasibility of the laser diode system 100, with the major improvements in laser weapon system level SWaP validated through experimentation. The present disclosure may use a 400 W single pump laser module integrated to the near zero pressure drop flow cavity using two-phase cooling with greatly reduced flow and improved thermal performance measured by the very small thermal wavelength change of the pump lasers and the improved weight density (in kW/kg) and lower pressure and flow requirements. The present disclosure may further use a 3 kW line replaceable fiber amplifier laser blade that is developed, which demonstrates the high cooling performance of the present disclosure while reducing SWaP and eliminating internal water connections from the fiber amplifier module and may be integrated into commercially available multi kW Modular Open System Architecture (MOSA) line replaceable 3 kW fiber laser amplifier blade for DE arrays.

The present disclosure not only addresses some major requirements for airborne laser weapons platforms but also has significant commercial applications, including handheld laser welding, metal additive manufacturing and for scientific laser arrays.

DE fiber amplifiers enabled with the present disclosure may reduce the number of water connections in a 3 kW fiber amplifier from 24 to zero. The low flow chamber may reduce the pressure drop in this amplifier from 15-25 psi to near zero. Additional weight reduction may be gained through the elimination of non-value add water connectors and that the flow chamber is also the structure for the fiber amplifier module. Overall system pump and cooling system complexity and infrastructure costs may be greatly reduced through the superior thermal performance of the facilitated two-phase cooling for the flow chamber of the present disclosure. This enhanced thermal performance may also allow for the use of more efficient non wavelength stabilized pump lasers as the thermal resistance from the laser emitters to the two-phase cooling fluid. In addition, the reduction in complexity afforded by the present disclosure may reduce the flow requirement by a factor of 5 and the reduction in overall module cost by 40%.

The present disclosure has the following advantages over the current approach: Thermal interfaces are eliminated over conduction cooling, thus eliminating the need for thermal interface materials and thermal interface loss and reliability reducing internal water interconnections are eliminated; Optimized for two-phase cooling with boiling initiating fin coatings; Flow Cavity allows for near zero pressure drop, and the Flow Cavity can also be used as a vapor chamber; and Non-DI water operation for common loop cooling, and additional circulation can be added to the flow chamber as reservoir to reduce overall flow rates.

The present disclosure combines the reliability benefits from a thermal conduction system with the thermal advantages of placing the flow tubes in the pump diode itself, while maintaining the weight reduction advantages of Euclid type fiber couple pumps, adding additional system-wide benefits of reducing pressure drop and flow requirements, positively impacting the overall cooling system by reducing the coolant pumping requirements. The present disclosure, when may be implemented into a MOSA type fiber amplifier blade, may lead to a reduction system flow requirements by a significant factor (e.g., factor of 5 or 10), while preserving the mass reductions and thermal performance of current mass reduced state of the art fiber coupled pump diodes.

The advantages are summarized in the following table:

| | Conduction | | | |
|---|---|---|---|---|
| Requirement/ | Cooled Fiber | SWAP | | |
| Specifications/ | Coupled | Reduced | | |
| Key Performance | Pumps (nLight, | internally | Optical | |
| Parameters/ | Lumentum, | cooled | Engines' | How & Why Optical |
| Specifications/ | Coherent, | FC | LASERFLOW | Engines' LASERFLOW |
| Attributes | Leonardo) | Pumps | technology | Achieves this |
| Performance | Acceptable | Excellent | Excellent | Fins directly bonded to a |
| | Requires high | Flow | | thin base plate extending |
| | flow to achieve | through | | into the flow removing |
| | this | the | | thermal interfaces |
| | | package | | |
| Weight | Poor | Excellent | Excellent | The thin baseplate with fins |
| | | | | reduces weight |
| Pressure Drop | Excellent | Poor | Excellent | Flow Cavity provides a large |
| | | | | flow area |
| Flow | High | High | Low | Recirculator in the flow |
| Requirement | | | | cavity acts as a thermal |
| | | | | battery |
| Reliability | Excellent | Poor | Excellent | No Internal Water |
| | | | | Connections, high reliability |
| | | | | O rings |
| Amenable to | Poor | Poor | Excellent | Fins with porous coatings to |
| two-phase | | | | promote boiling |
| Cooling | | | | |
| Thermal Battery | External Heavy | External | Internal | No heavy wax PCM two |
| Options | | Heavy | Lightweight | phase with battery provides |
| | | | | thermal battery |

In operation, all fiber lasers (e.g., laser diodes 102) include two key components: 1) An array of fiber coupled pump lasers emitting low-cost laser light at nearly 100 times the diffraction limit, and 2) a rare earth doped gain fiber laser or amplifier harness that converts the pump light into a near diffraction limited output beam. For the most used ytterbium (Yb) fiber gain system, the pump lasers covert about half of the electrical power into usable light and the other half into waste heat. The fiber laser or amplifier harness coverts the supplied pump light into output laser light with over 80% efficiency. The driver electronics typically are over 97% efficiency. Therefore, for every 1 kW of electrical power provided to the fiber laser system, 60% of this delivered power is waste heat that must be rejected to the surrounding environment. This means that for a 300 kW class laser would require dissipating in excess of 600 kW of heat. A 30 second engagement magazine would require 18 MJ of energy to store or reject. Because it is desirable to have the laser system be as compact as possible, either liquid cooling to a compressor or radiator is the primary means for rejecting this waste heat.

Since the pump lasers themselves produce 80%-90% of the system waste heat, focusing on this thermal pathway may have the largest impact on improving the overall laser weapon system design. Early DE lasers were solid state lasers pumped by laser diode stacks cooled by microchannel coolers. While these pump lasers were extremely compact the microchannel coolers required complicated and separate deionized (DI) water cooling loops and experienced pressure drops in excess of 50 PSI.

The advent of more rugged and reliable fiber laser arrays brought the conduction cooled, high brightness, fiber coupled laser pumps into use with power levels from 150 W to 600 W in various size and NA pump fibers. The environmental sensitivity of the semiconductor laser diodes requires that the pump lasers be enclosed in a separate hermetically sealed package. A typical 3 kW+ fiber amplifier might use 28 150 W high brightness diodes are six 600 W pump lasers of lower brightness. The conventional approach is to tightly fasten these pumps to a large (and very heavy) water cooled copper cold plate with flow rates of 2 gal/min for every 1 kW of pump light delivered. The sensitivity of the fiber coupling “optics bench” in each laser to external mechanical stresses requires a large copper sub mount to keep the optics bench stable. Thus a 3.5 kW laser module using these diodes will require 8 gal/min of water flow and will weigh over 50 kG.

Recent investments have produced excellent results in improving thermal performance resulting in a higher power per pump laser volume and weight densities of under 0.4 kg per kW of pump power. This unfortunately has been achieved by building the cooling fluid circulating lines inside the pump laser package resulting in a large number of internally leak prone water connections inside the amplifier module. A 3 kW fiber amplifier module having 6×600 W pump lasers would contain 24 water connections in the package drastically reducing the expected reliability of the laser. The narrow fluid passageways through the pump lasers also results in increased pressure drop resulting in more pumping capacity required by the system. These state-of-the-art lasers are not amenable to two-phase cooling either, as there are no dedicated locations to promote vapor formation.

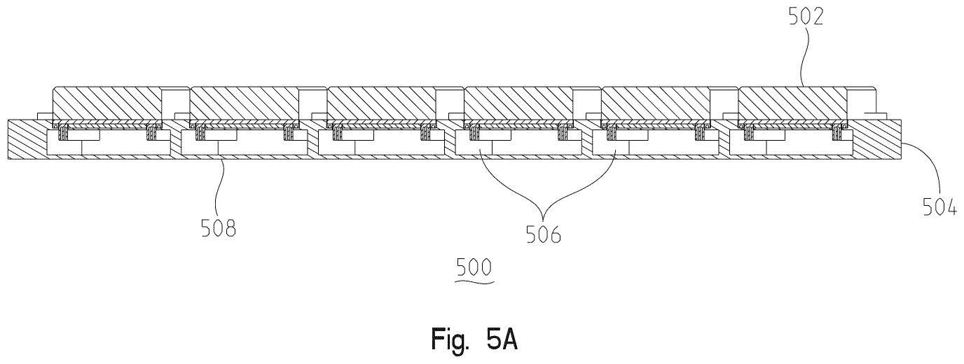

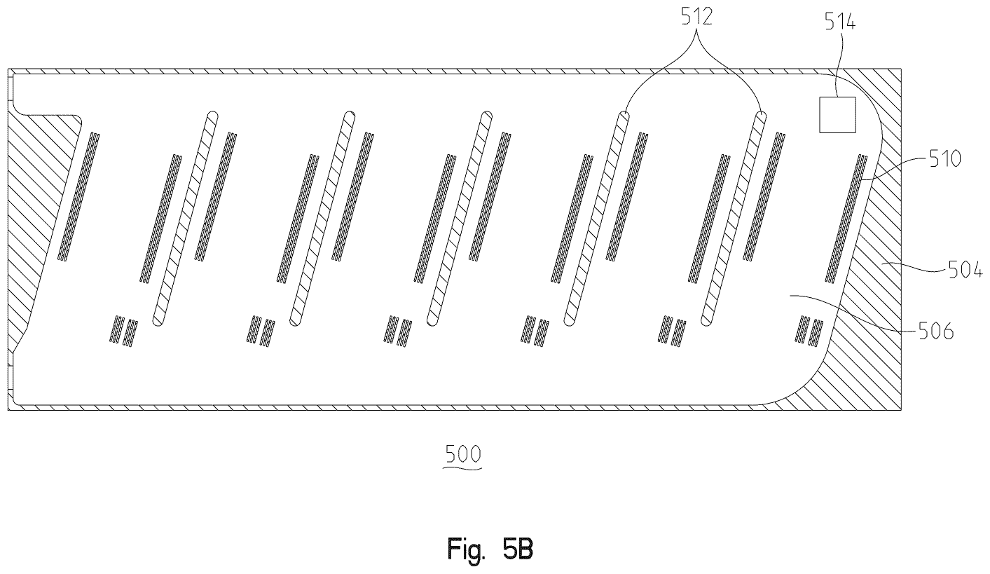

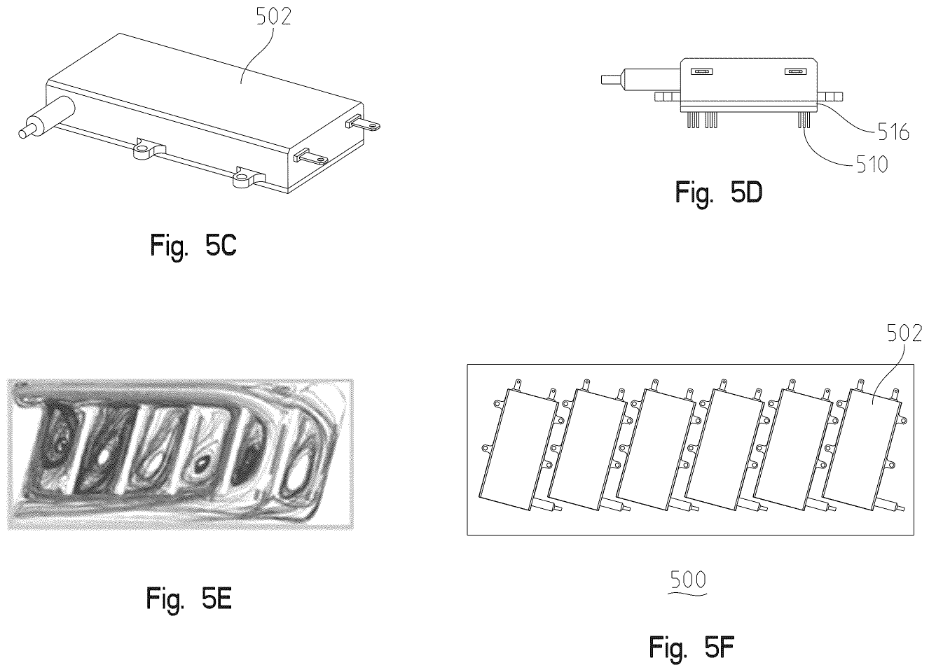

Accordingly, the present disclosure uses an innovative and novel solution. For instance, as shown in FIGS. 5A and 5B and described above, the present disclosure solves the problems of the prior approaches by bringing the fluid flow (e.g., cooling medium) closer to the internal laser diode sub mounts and the cooled pump laser modules. For instance, this is achieved by mounting (e.g., bonding) the two-phase cooling optimized coated fins directly onto the laser emitters and then placing the fins directly into the flow of the cooling fluid (e.g., cooling medium) in a large cavity with low flow and near zero pressure drop characteristics. For example, FIGS. 5A and 5B show a laser diode system 500, which may be the same or a variation of the laser diode system 100 described above. The laser diode system 500 includes lasers 502 and a cold plate 504. The cold plate 504 includes a flow cavity 506 and a cooled underside 508 of the cold plate 504. The lasers 502 may be light-weighted pump lasers with “in the flow” bonded fins (e.g., the copper fins 108). The flow cavity 506 may be a 3D printed hollow flow cavity and in some examples, may include flow directors and/or baffles. The cooled underside 508 may be used for mounting gain fiber and/or fiber amplifier components.

In some instances, a dual O ring system provides for a leak proof seal and a soft mounting to minimize the mechanical stress placed on the pump laser internal optics bench, like the internally cooled laser, the fluid is closely coupled to the emitters, allowing for large package weight reductions, but unlike these units, there are no package level water connections, creating a more reliable fiber amplifier while achieving all of the cooling improvements and weight reductions of these current state of the art pump lasers.

In some examples, the present disclosure provides a 3600 W fiber amplifier Plate (e.g., a carbon fiber plate) with “in the flow” pump lasers 502 for enhanced thermal performance. For instance, a typical laser pump module will have its heat generating laser emitters aligned in one or two rows.

FIG. 5B shows a top view of the laser diode system 500. FIG. 5B shows the flow cavity 506, copper fins 510, flow directors 512, and a pump 514 (e.g., an auxiliary pump). The fins 510 may be pump mounted cooling fins protruding into the flow cavity 506 of the cold plate 504. For example, referring to FIGS. 5A and 5B, a concentrated heat generating region provides an opportunity for reducing the weight of the module by concentrating the cooling onto the thermal conduction of this region. In these FIGs., a lightweight stiff material such as a thin carbon fiber plate is layered on top by a thin coefficient of thermal expansion (CTE) matched copper layer. Slots uncovering these heat generating areas are removed from the carbon fiber plate and porous boiling initiating fins (e.g., fins 510) are bonded to the thin copper (Cu) plate. This bonded and finned plate becomes the base for the optics bench and soldering the heat spreading blocks that the laser emitters are bonded to. This provides a rigid base for the pump lasers while providing excellent thermal conduction to the cooling liquid (e.g., cooling fluid). In some instances, a commercial-off-the-shelf (COTS) pump laser may be used with bonded fins; in other instances, custom made bonded base plate pump lasers may be used. The carbon fiber base plate also has in it two parallel grooves (e.g. the O-ring channel 202 shown in FIG. 2D) for soft O rings (e.g., a dual O ring system) that when the pump laser 502 is gently bolted to the flow cavity, the O rings may provide a gentle, non-stress inducing mounting that is leak proof.

The bonded, lightweight pump module (e.g., pump laser 502) may be bonded to a specially designed flow cavity. This cavity may be a wide flow region that the fins 510 of the pump module sit into which has designed baffles to create turbulent flow under the pump lasers 502. The relatively large flow area may provide a near zero pressure drop and also a reservoir for creating a circulating two-phase thermal battery. The cooling fluid may flow into the cavity and be distributed through a parallel manifold to multiple pump lasers 502 and then out through another manifold to the condenser radiator of the overall cooling system. An additional circulating pump (e.g., auxiliary pump 514) that may add additional circulation through the pump lasers 502 may be used and added to allow for reduced overall flow in the system. The design of the flow cavity may be optimized. For instance, the materials used such as 3D printed metals or one or more polymers, and the optimal placement and flow characteristics of the flow re-circulator, as well as providing common loop cooling for the fiber amplifier and driver electronics may be used for the laser diode system 500.

FIGS. 5C, 5D, and 5F show additional views of the laser diode system 500. For example, FIG. 5C shows the pump laser 502 and the copper fins 510. The pump laser 502 may be a 600 Watt Fiber Coupled Pump with a 55% electrical-to-optical (E-O) efficiency. Further, in some examples, the pump laser 502 may generate 500 Watts of heat, and 90% of this heat may be generated by the copper fins 510. FIG. 5D shows the fins 510, a thin copper (CU) base 516, and the cold plate 504. The cold plate 504 may be a Carbon (C) Fiber plate. The fins 510 may be bonded directly to the plate 504. The present disclosure may reduce SWAP and improve performance by using the thin copper base 516 and adding the carbon fiber stiffening plate 504 with slots to expose the CU base 516 with porous CU fins 510 that are added to directly connect the diode region to the fluid flow. FIG. 5F shows a plurality of lasers 502 with the flow cavity 506. The plate 504 may be 3600 W fiber amplifier plate that includes 3D printed flow cavities with fiber laser components mounted onto the opposite side. FIG. 5E shows a flow model for the flow of the cooling medium within the flow cavity of the plate (e.g., the flow cavity 506 and the plate 504 shown in FIGS. 5A and 5B).

The current three primary methods for cooling kW class DE laser systems, microchannel coolers, conduction cooling or internally cooled units all face severe drawbacks that keep DE lasers from having the weight, reliability, and support infrastructure needed for the systems to have widespread deployments on a wide array of platforms. The present disclosure combines the best of these prior approaches to create a high-performance thermal management system that is lightweight, reliable and has substantially reduced cooling and pumping infrastructure support requirements to facilitate multiple applications including future laser weapons becoming a widespread reality.

In some examples, the present disclosure may use a 400 Watt (W) single pump laser thermal system. The thermal performance may be modelled and the design iterated for full system optimization. In some instances, the present disclosure may use a 3 kiloWatt (kW) MOSA type laser blade with over a 10× reduction for system cooling infrastructure, resulting in an engineering product that can be commercialized in industries to improve laser system SWAP and reduce the support infrastructure needed to operate these lasers in defense, industrial and scientific applications.

In some variations, the present disclosure may use thermal simulation software for the design of the single pump module experimental demonstrator to design the laser diode system 500. Through an iterative modelling process, a factor of 2-3 in thermal performance over current conductive devices may be achieved. Another factor of 2 to 3 improvement may be obtained from using a 2 phase cooling process. Uniform and consistent cooling may be expected. Flow rates and pump unit critical temperatures may be key metrics. As such, an optimized flow cavity fluid pathway may be used and this single pump design may expanded to a 6 pump module blade.

In some instances, the present disclosure may fabricate the 400 W single pump system by first fabricating through subtractive machining and later though additive machining. An e24 fiber coupled pump and/or OEI laser driver may be used. The O-ring sealing assembly (e.g., dual O ring system) under the pump laser 502 and testing may be designed to ensure a non-leaking system.

Furthermore, in some examples, the present disclosure fabricates a complete cooling system for both single phase and two phase cooling to validate overall system models to show the improvements of the laser diode system. This system may include the designed single pump e24 laser diode with bonded fins, the designed flow cavity, and a chiller pumping system. The pump laser may be powered to 400 W of output and its output power will be measured on a power meter. A thermal camera may also monitor the pump laser for any hot spots to occur as a result of the mounting process. An optical spectrum analyzer may monitor the wavelength of the output laser to detect for thermally related wavelength shifts as this is the most sensitive measurement of thermal performance.

In some instances, the present disclosure may operate with a single 400 W modified commercially available pump laser 502 utilizing in the flow technology, the flow cavity a re-circulator in the flow cavity for the thermal battery and may use a two-phase coolant to measure the full advantages of the system. Output power and pump wavelength may be key measurements. This flow cavity may serve to validate the models and designs that are developed. An iterative process may be conducted to create multiple systems. Key metrics may be the pump laser chip temperature as measured by the wavelength shift of the pump laser diodes as a function of chip temperature.

In some variations, the present disclosure may be configured for full MOSA Laserblade design. For instance, the results of the single and 2 phase cooling may be assessed and then viewed in the context of a full DE laser weapon thermal model. This may be used for the thermal management system of the overall system SWAP and infrastructure.

In some examples, the present disclosure may be applied as well (with modifications) to any kW class laser that is liquid cooled, particularly industrial lasers, and is especially useful for applications that are high power, mobile and compact. It may be used, for example, to provide mobile welding and cutting services.

Because of the use of fiber coupled pump laser diodes, using mainly COTS components, and because of the ability of the present disclosure to address SWAP reduction, reliability improvements and system cooling infrastructure reductions, the present disclosure meets rigid requirements (unlike current technologies). As a result, the present disclosure has advantages in cost and performance over the competitors. These advantages include reduced cooling pump and flow requirements, reliability improvements and the ability to work with airborne high air flow cooling as well. With performance and cost in mind, additional improvements may be made by incorporating the latest development to existing sensors components.

FIG. 6 shows a block diagram 600 of the laser diode system 100 and/or 500. For instance, the block diagram 600 includes a diode 602 (e.g., an E24 diode 602), a direct coolant interface 604, a cold plate 606, a coolant chiller 608, and a coolant pump 610. The straight arrows denote the heat moving through the system and the dotted arrows denote the cooling moving through the system. As mentioned above, a fiber coupled, electrically driven, multi-emitter semiconductor laser (e.g., diode 602) used for both pumping other lasers or for direct diode applications, generally has an electrical optical efficiency that is around 50%. This means that for every Watt of useful light generated, one Watt of waste heat is generated as well. If this waste heat is allowed to reside at its origination point, the build-up of heat will become severe and damage the laser diode system 100 and/or 500. As such, a method of removing this waste heat from the location of laser diode devices (e.g., diode 602) is provided. For instance, the diode 602 includes an arrow for thermal load, which indicates the heat generated while the direct diode applications are in use.

The laser diode chips (e.g., the diode 602) that include the emitters that generate the heat are very small, typically on the order of 5 mm square. The emitter itself is typically 0.15 mm wide by 4 mm long. These laser diode chips may be bonded by solder to a highly conductive copper-tungsten alloy mount to spread the heat as much as possible. The sensitivity of the laser diode chips to the environment requires that the chips themselves be mounted into a hermetically sealed package with means for bringing in the electrical current, coupling out the emitted light, and conducting the heat away from the laser diode chips.

In some instances, at powers under 500 W per package, the laser diode devices can be mounted through a thermal interface (e.g., using industry accepted thermal interface materials) to a heatsink that is coupled to the environment by way of a fan or blower that blows cold air across the heat sink and by way of convective cooling, the waste heat is transferred to the blowing air and hence rejected or transferred to the outer environment.

In some examples, at powers greater than 500 W or places where convective airflow is not possible, a method to conduct the heat out of the package to a flowing liquid material is desired. This liquid transfer material (e.g., the direct coolant interface 604) can be either water, or ethylene glycol or some kind of 2 phase refrigerant. In this configuration, the heat from the laser diode devices (e.g., the diode 602) is transferred to the liquid (e.g., the liquid of the direct coolant interface 604) and transported away from the laser diode devices. Ultimately, this waste heat is to be transferred from the liquid to the environment by a liquid to air heat exchanger (e.g., the coolant chiller 608) that uses still or forced air to complete this transfer of heat to the environment, which is shown by the rejected heat that is dissipated from the system. In this case, a pump (e.g., the coolant pump 610) is used to circulate the liquid from the cold plate (e.g., cold plate 606) where the heat is transferred from the laser diode device to the liquid and the liquid to air heat exchanger and to the outside environment. In other words, the diode 602 generates heat that is taken away by a direct coolant interface 604 such as a liquid material. The cold plate 606 is used to circulate the liquid material of the direct coolant interface 604. The coolant chiller 608 obtains the heat from the cold plate 606 and is a liquid to air heat exchanger that uses still or forced air to complete the transfer of heat to the environment. The coolant pump 610 is used to circulate the liquid from the cold plate 606 to the coolant chiller 608, and back in order to cool the diode 602.

In other words, using the block diagram 600 (e.g., the laser diode system 100 described above), the laser diode system may cool the laser diodes when the laser diodes are performing DE applications. For instance, a control system, which may be included within the laser diode system and/or separate from the laser diode system, may control the laser diode system. For example, the control system may include one or more controllers, processors, and/or memory. The control system may operate the laser diodes (e.g., laser diodes 102) to perform one or more DE applications. Further, the control system may control cooling of the laser diodes (e.g., the laser diodes 602) during operation. For instance, the control system may control a pump (e.g., the pump 610) to circulate the cooling medium through a cold plate (e.g., cold plate 606) to cool the laser diodes. As mentioned above, the laser diodes may be coupled to copper fins and the copper fins may be embedded within the copper fin cavities of the interior cavity of the cold plate. The control system may control the coolant pump to circulate the cooling medium through the interior cavity to cool the laser diodes. In some instances, the laser diode system includes a coolant chiller and the control system circulates the cooling medium through the cold plate to the coolant chiller. The coolant chiller may be a liquid to air heat exchanger that uses still or forced air to transfer waste heat from the one or more laser diodes to an outside environment.

It will be appreciated that the various machine-implemented operations described herein may occur via the execution, by one or more respective processors, of processor-executable instructions stored on a tangible, non-transitory computer-readable medium, such as a random access memory (RAM), read-only memory (ROM), programmable read-only memory (PROM), and/or another electronic memory mechanism. Thus, for example, operations performed by any device described herein may be carried out according to instructions stored on and/or applications installed on the device, and via software and/or hardware of the device.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and “at least one” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. A laser diode system, comprising:
one or more laser diodes;
a plurality of copper fins coupled to the one or more laser diodes; and
a cold plate comprising a plurality of copper fin cavities and an interior cavity, wherein the plurality of copper fins are embedded within the plurality of copper fin cavities, and wherein a cooling medium is circulated through the interior cavity to cool the one or more laser diodes.

2. The laser diode system of claim 1, further comprising:
a direct coolant interface that is positioned between the cold plate and the one or more laser diodes, wherein the direct coolant interface transfers waste heat away from the one or more laser diodes to the cold plate.

3. The laser diode system of claim 2, wherein the cooling medium comprises a liquid transfer material, and wherein the direct coolant interface uses the liquid transfer material to transfer the waste heat away from the one or more laser diodes to the cold plate.

4. The laser diode system of claim 1, further comprising:
a coolant pump, wherein the coolant pump is configured to circulate the cooling medium from the cold plate to a coolant chiller, and back to the cold plate; and
the coolant chiller, wherein the coolant chiller is a liquid to air heat exchanger that uses still or forced air to transfer waste heat from the one or more laser diodes to an outside environment.

5. The laser diode system of claim 4, wherein the interior cavity of the cold plate comprises two openings, and wherein the coolant pump circulates the cooling medium into the cold plate using the two openings.

6. The laser diode system of claim 4, wherein the interior cavity of the cold plate comprises flow directors and/or baffles that are configured to cause turbulence within the interior cavity of the cold plate.

7. The laser diode system of claim 1, wherein the cooling medium is a liquid-based cooling medium that is circulate through the interior cavity.

8. The laser diode system of claim 1, wherein the cooling medium is an air-based cooling medium that is circulate through the interior cavity.

9. The laser diode system of claim 1, wherein each of the one or more laser diodes comprises a first portion and a second portion, wherein the first portion generates more waste heat than the second portion, and wherein the plurality of copper fins are coupled to the first portion of the one or more laser diodes.

10. The laser diode system of claim 1, further comprising:
a copper heat spreader; and
an aluminum seal, wherein the copper heat spreader and the aluminum seal are positioned between the one or more laser diodes and the cold plate.

11. A cold plate, comprising:
a plurality of copper fin cavities; and
an interior cavity, wherein a plurality of copper fins that are coupled to one or more laser diodes are embedded within the plurality of copper fin cavities, and wherein a cooling medium is circulated through the interior cavity to cool the one or more laser diodes.

12. The cold plate for claim 11, wherein a direct coolant interface is positioned between the cold plate and the one or more laser diodes, wherein the direct coolant interface transfers waste heat away from the one or more laser diodes to the cold plate.

13. The cold plate for claim 12, wherein the cooling medium comprises a liquid transfer material, and wherein the direct coolant interface uses the liquid transfer material to transfer the waste heat away from the one or more laser diodes to the cold plate.

14. The cold plate for claim 11, wherein the interior cavity of the cold plate comprises two openings, and wherein a coolant pump circulates the cooling medium into the cold plate using the two openings to transfer waste heat from the one or more laser diodes to an outside environment.

15. The cold plate for claim 11, wherein the interior cavity of the cold plate comprises flow directors and/or baffles that are configured to cause turbulence within the interior cavity of the cold plate.

16. A method for cooling one or more laser diodes of a laser diode system, comprising:
operating the one or more laser diodes to perform direct energy (DE) applications; and
circulating, using a coolant pump, a cooling medium through a cold plate of the laser diode system to transfer waste heat from the one or more laser diodes to an outside environment, wherein a plurality of copper fins are coupled to the one or more laser diodes, wherein the plurality of copper fins are embedded within a plurality of copper fin cavities of an interior cavity of the cold plate, and wherein coolant pump circulates a cooling medium through the interior cavity to cool the one or more laser diodes.

17. The method of claim 16, wherein the laser diode system comprises a coolant chiller, and wherein circulating the cooling medium comprises:
circulating the cooling medium through the cold plate to the coolant chiller, wherein the coolant chiller is a liquid to air heat exchanger that uses still or forced air to transfer waste heat from the one or more laser diodes to an outside environment.

18. The method of claim 17, wherein the interior cavity of the cold plate comprises two openings, and wherein circulating the cooling medium through the cold plate comprises circulating the cooling medium through the two openings.

19. The method of claim 16, wherein the interior cavity of the cold plate comprises flow directors and/or baffles that are configured to cause turbulence within the interior cavity of the cold plate when the coolant pump circulates the cooling medium through the cold plate.

20. The method of claim 16, wherein each of the one or more laser diodes comprises a first portion and a second portion, wherein the first portion generates more waste heat than the second portion, and wherein the plurality of copper fins are coupled to the first portion of the one or more laser diodes.
